(19) United States
(12) Patent Application Publication
(10) Pub. No.: US 2015/0144989 A1
(43) Pub. Date: May 28, 2015

(54) POWER SEMICONDUCTOR DEVICE AND METHOD OF MANUFACTURING THE SAME

(71) Applicant: SAMSUNG ELECTRO-MECHANICS CO., LTD., Suwon-Si (KR)

(72) Inventors: Dong Soo SEO, Suwon-Si (KR); In Hyuk SONG, Suwon-Si (KR); Jae Hoon PARK, Suwon-Si (KR); Kee Ju UM, Suwon-Si (KR); Chang Su JANG, Suwon-Si (KR)

(73) Assignee: SAMSUNG ELECTRO-MECHANICS CO., LTD., Suwon-Si (KR)

(21) Appl. No.: 14/266,121

(22) Filed: Apr. 30, 2014

(30) Foreign Application Priority Data
Nov. 28, 2013 (KR) 10-2013-0146403

(51) Int. Cl. H01L 29/739; H01L 29/66

(52) U.S. Cl. CPC H01L 29/7393; H01L 29/66325
USPC 257/139; 438/135

(57) ABSTRACT

A power semiconductor device may include: a first semiconductor region having a first conductivity type; a second semiconductor region having a second conductivity type and formed on the first semiconductor region; a third semiconductor region having the first conductivity type and formed in an upper portion of the second semiconductor region; a trench gate formed to penetrate from the third semiconductor region to the first semiconductor region, having a gate insulating layer formed on a surface thereof, and filled with a conductive material; and a fourth semiconductor region having the second conductivity type and formed to penetrate through the second semiconductor region.

### CROSS-REFERENCE TO RELATED APPLICATION

This application claims the benefit of Korean Patent Application No. 10-2013-0146403 filed on Nov. 28, 2013, with the Korean Intellectual Property Office, the disclosure of which is incorporated herein by reference.

### BACKGROUND

The present disclosure relates to a power semiconductor device and a method of manufacturing the same.

An insulated gate bipolar transistor (IGBT) is a transistor manufactured to have bipolarity by forming a gate using a metal oxide semiconductor (MOS) and forming a p-type collector layer on a rear surface thereof.

Ever since power metal oxide semiconductor field effect transistors (MOSFETs) were developed in the related art, they have been used in fields requiring high speed switching characteristics.

However, due to inherent structural limitations of MOSFETs, bipolar transistors, thyristors, gate turn-off (GTO) thyristors, and the like, have been used in fields requiring the application of high levels of voltage thereto.

Since IGBTs have low forward loss and rapid switching speed characteristics, the application of the IGBT has increased in fields to which existing thyristors, bipolar transistors, MOSFETs and the like may not be applied.

The operational principle of IGBTs will hereinafter be described. In the case in which an IGBT is turned on, when a voltage applied to an anode is higher than a voltage applied to a cathode and a voltage higher than a threshold voltage of the IGBT is applied to a gate electrode, a polarity of a surface of a p-type body region positioned at a lower end of the gate electrode may be inverted, such that an n-type channel is formed.

An electron current injected into a drift region though the channel induces the injection of a hole current from a high-concentration p-type collector layer positioned in a lower portion of the IGBT, similar to a base current of a bipolar transistor.

Due to the injection of minority carriers at a high concentration, conductivity modulation, in which conductivity in the drift region is increased by several tens to several hundreds of times, may occur.

Unlike a MOSFET, in an IGBT, a resistance component in the drift region thereof may be reduced to be extremely small, due to conductivity modulation. Therefore, the IGBT may allow very high levels of voltage to be applied thereto.

Current flowing to the cathode is divided into an electron current flowing through the channel and a hole current flowing through a p-n junction between a p-type body region and an n-type drift region.

Since the IGBT has a pnp structure between the anode and the cathode in a structure of a substrate, the IGBT does not have a diode embedded therein unlike the MOSFET, and thus, a separate diode should be connected in reverse parallel with the IGBT.

The main characteristics of such an IGBT reside in maintenance of a breakdown voltage, a decrease in conduction loss, and an increase in switching speed.

A structure of the IGBT will hereinafter be described. Since the IGBT is formed of an n+ type emitter region, a p type body region, an n− type drift region, and a p+ type collector region, there is provided a p-n-p-n parasitic thyristor structure.

Once the parasitic thyristor is operated, the IGBT may be in a state in which it is no longer adjusted by the gate, such that a significant amount of current flows through the anode and the cathode and a large amount of heat is generated, leading to defects.

A phenomenon in which a parasitic thyristor is turned on is referred to as latch-up.

Since latch-up may significantly decrease device reliability, a method of preventing such a problem has been demanded.

The following Related Art Document (Patent Document 1) relates to a semiconductor device.

### RELATED ART DOCUMENT

(Patent Document 1) Japanese Patent Laid-Open Publication No. 2005-210047

### SUMMARY

An aspect of the present disclosure may provide a power semiconductor device having improved reliability.

According to an aspect of the present disclosure, a power semiconductor device may include: a first semiconductor region having a first conductivity type; a second semiconductor region having a second conductivity type and formed on the first semiconductor region; a third semiconductor region having the first conductivity type and formed in an upper portion of the second semiconductor region; a trench gate formed to penetrate from the third semiconductor region to the first semiconductor region, having a gate insulating layer formed on a surface thereof, and filled with a conductive material; and a fourth semiconductor region having the second conductivity type and formed to penetrate through the second semiconductor region.

The fourth semiconductor region may have an impurity concentration higher than that of the second semiconductor region.

The fourth semiconductor region may be formed to be spaced apart from the trench gate.

The power semiconductor device may further include a fifth semiconductor region having the first conductivity type and formed to be spaced apart from the trench gate below the fourth semiconductor region.

The fifth semiconductor region may be formed to contact the fourth semiconductor region.

The fifth semiconductor region may have an impurity concentration higher than that of the first semiconductor region.

According to another aspect of the present disclosure, a method of manufacturing a power semiconductor device may include: preparing a first semiconductor region having a first conductivity type; forming a trench gate by etching the first semiconductor region, forming a gate insulating layer on a surface thereof, and filling a conductive material therein; forming a second semiconductor region by implanting second conductivity type impurities into an upper portion of the first semiconductor region; forming a third semiconductor region by implanting first conductivity type impurities into an upper portion of the second semiconductor region; and forming a fourth semiconductor region by implanting the second conductivity type impurities to be extended from the second semiconductor region to the first semiconductor region.

The fourth semiconductor region may be formed by implanting a greater amount of impurities than the second semiconductor region.

The fourth semiconductor region may be formed to be spaced apart from the trench gate.

The method may further include forming a fifth semiconductor region to be spaced apart from the trench gate below the second semiconductor region by implanting the first conductivity type impurities.

The fifth semiconductor region may be formed to contact the fourth semiconductor region.

The fifth semiconductor region may be formed by implanting a greater amount of impurities than the first semiconductor region.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 illustrates a schematic cross-sectional view of a power semiconductor device according to an exemplary embodiment of the present disclosure;

FIG. 2 illustrates a schematic cross-sectional view of a power semiconductor device according to another exemplary embodiment of the present disclosure;

FIG. 3 illustrates a schematic cross-sectional view of a power semiconductor device according to another exemplary embodiment of the present disclosure;

FIG. 4 illustrates a schematic cross-sectional view of a power semiconductor device according to another exemplary embodiment of the present disclosure; and

FIG. 5 is a flowchart schematically illustrating a method of manufacturing a power semiconductor device according to an exemplary embodiment of the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A power switch may be configured as any one of a power metal oxide semiconductor field effect transistor (MOSFET), an insulated gate bipolar transistor (IGBT), several types of thyristor, and devices similar thereto. Most new technologies disclosed herein will be described based on IGBT technology. However, several exemplary embodiments of the present disclosure disclosed herein are not limited to IGBT technology. The present inventive concept may be applied to other types of power switch including power MOSFETs and several types of thyristor. Further, several exemplary embodiments of the present disclosure will be described as including specific p-type and n-type regions. However, conductivity types of several regions disclosed herein may be similarly applied to devices having conductivity types opposite thereto.

In addition, n-type or p-type as used herein may be defined as a first conductivity type or a second conductivity type. Meanwhile, the first and second conductivity types are different conductivity types.

Further, generally, positive ‘+’ refers to a state in which a region is heavily doped and negative ‘−’ refers to a state that a region is lightly doped.

For clarification, the first conductivity type will be referred to as an n-type and the second conductivity type will be referred to as a p-type, but the present disclosure is not limited thereto.

In addition, a first semiconductor region represents adrift region, a second semiconductor region represents a body region, a third semiconductor region represents an emitter region, a fourth semiconductor region represents a hole movement region, and a fifth semiconductor region represents a hole accumulation region, but the semiconductor regions are not limited thereto.

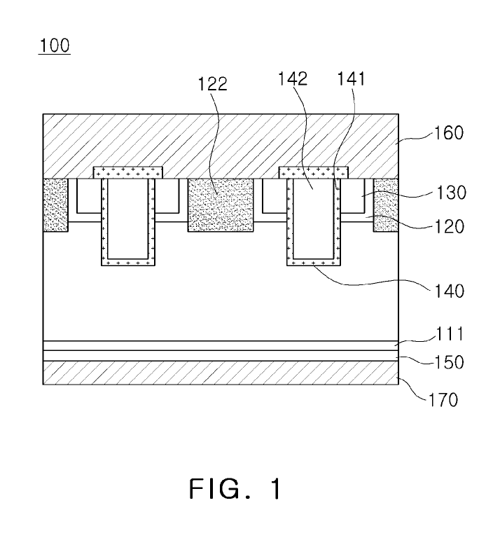

FIG. 1 illustrates a schematic cross-sectional view of a power semiconductor device according to an exemplary embodiment of the present disclosure.

A power semiconductor device 100 according to an exemplary embodiment of the present disclosure will be described with reference to FIG. 1. The power semiconductor device 100 according to the exemplary embodiment of the present disclosure may include a collector region 150, a drift region 110, a body region 120, and an emitter region 130.

The drift region 110 may be formed by implanting n-type impurities.

Therefore, the drift region 110 may be relatively thick in order to maintain a breakdown voltage of the power semiconductor device.

The drift region 110 may further include a buffer region 111 formed therebelow.

The buffer region 111 may be formed by implanting n-type impurities into a lower portion of the drift region 110.

The buffer region may serve to block extension of a depletion region of the power semiconductor device at the time of the extension of the depletion region, thereby assisting in maintaining a breakdown voltage of the power semiconductor device.

Therefore, in the case in which the buffer region is formed, a thickness of the drift region 110 may be decreased, such that the power semiconductor device may be miniaturized.

The body region 120 may be formed by implanting p-type impurities into an upper portion of the drift region 110.

The body region 120 may have a p-type conductivity to form a p-n junction with the drift region 110.

The body region 120 may be formed in the upper portion of the drift region 120 to have a stripe shape.

The emitter region 130 may be formed by implanting n-type impurities at a high concentration into an upper portion of the body region 120.

A trench gate 140 may be formed to extend from the emitter region 130 to the drift region 110 through the body region 120.

That is, the trench gate 140 may penetrate from the emitter region 130 into a portion of the drift region 110.

The trench gates 140 may be formed to be elongated in one direction and may be arranged at predetermined intervals in a direction perpendicular to the direction in which the trench gates 140 are elongated.

The trench gate 140 may have a gate insulating layer 141 formed in a portion thereof in contact with the drift region 110, the body region 120, and the emitter region 130.

The gate insulating layer 141 may be formed of a silicon oxide (SiO₂), but is not limited thereto.

The trench gate 140 may be filled with a conductive material 142.

The conductive material 142 may be a polysilicon (poly-Si) or a metal, but is not limited thereto.

The conductive material 142 may be electrically connected to a gate electrode (not shown) to control an operation of the power semiconductor device 100 according to the exemplary embodiment of the present disclosure.

In the case in which a positive voltage is applied to the conductive material 142, a channel C may be formed in the body region 120.

In detail, in the case in which the positive voltage is applied to the conductive material 142, electrons present in the body region 120 may be drawn toward the trench gate 140 and collected around the trench gate 140, such that the channel C may be formed.

That is, electrons and holes may be recombined with each other in a p-n junction, such that the trench gate 140 draws the electrons toward a depletion region in which carriers are not present to form the channel C, whereby a current may flow through the channel.

The collector region 150 may be formed by implanting p-type impurities into a lower portion of the drift region 110 or into a lower portion of the buffer region.

In the case in which the power semiconductor device is an IGBT, the collector region 150 may provide holes to the power semiconductor device.

Due to injection of the holes, which are minority carriers at a high concentration, conductivity modulation, in which conductivity in the drift region is increased by several tens to several hundreds of times, occurs.

An emitter metal layer 160 may be formed on exposed upper surfaces of the emitter region 130 and the body region 120, and a collector metal layer 170 may be formed on a lower surface of the collector region 150.

As described above, the power semiconductor device according to the exemplary embodiment of the present disclosure may include a parasitic thyrister having a p-n-p-n structure from a bottom thereof.

Once the parasitic thyristor is operated, the IGBT may have a state in which it is no longer adjusted by the gate, such that a significant amount of current flows in the anode and the cathode and a large amount of heat is generated, thereby burning the device.

A phenomenon in which the parasitic thyristor is turned on is referred to as latch-up.

Specifically describing a principle by which latch-up occurs, when the power semiconductor device is operated, the electron current may flow through the channel and the hole current may overpass a junction surface of the body region 120 to thereby flow into the emitter metal layer 160.

Since the electron current is injected into the drift region 110 below the bottom of the trench gate 140 along the channel to thereby increase conductivity of the drift region 110, most of the hole current may be injected from the body region 120 below the channel and flow into the emitter metal layer 160 through a lower portion of the emitter region 130.

In the case in which the hole current is increased and a voltage drop across the lower portion of the emitter region 130 is larger than a potential barrier of an interface between the emitter region 130 and the body region 120, a junction may have a forward bias, whereby the electrons may be injected from the emitter region 130 to the body region 120 and a parasitic n-p-n thyristor including an n-type emitter region 130, a p-type body region 120, and an n-type drift region 110 may be operated.

Therefore, it is necessary to prevent the hole current from being increased in the lower portion of the emitter region 130.

Referring to FIG. 1, the power semiconductor device 100 according to the exemplary embodiment of the present disclosure may include a hole movement region 122.

The hole movement region 122 may be formed by implanting p-type impurities at a high concentration.

For example, an impurity concentration of the hole movement region 122 may be higher than that of the body region 120.

A portion of the hole movement region 122 may be formed to penetrate through the body region 120 to thereby be in contact with the drift region 110.

Since the hole movement region 122 is formed by using high concentration p-type impurities, it may have a very low resistance against the hole current.

Since the portion of the hole movement region 122 is formed to contact the drift region 110, the holes accumulated in the drift region 110 may flow into the hole movement region 122 and may be discharged into the emitter metal layer 160.

That is, the hole movement region 122 may prevent the parasitic thyristor from being operated by preventing the holes from being overpassed to the emitter region 130.

Therefore, in the case in which the hole movement region 122 is formed, reliability of the power semiconductor device 100 may be improved.

In addition, the hole movement region 122 may be formed to be spaced apart from the trench gate 140.

For example, the hole movement region 122 may be formed to be spaced apart from the trench gate 140 by a width of the channel to be formed when the power semiconductor device 100 is turned on.

The hole movement region 122 is formed to be spaced apart from the trench gate 140, such that an increase in a turn-on voltage of the power semiconductor device 140 may be prevented.

Therefore, the power semiconductor device 100 according to the exemplary embodiment of the present disclosure may have a low turn-on voltage and high reliability.

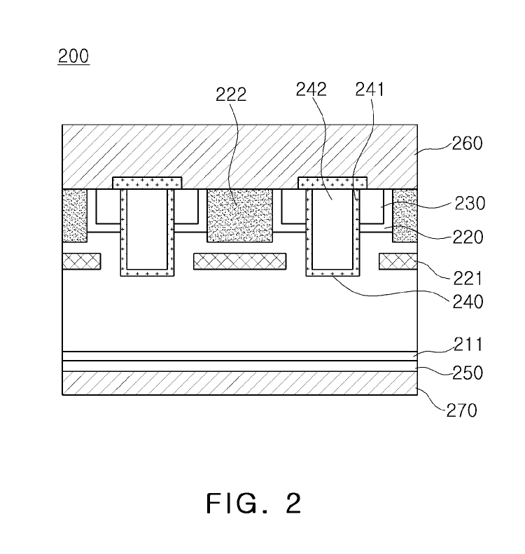

FIG. 2 illustrates a schematic cross-sectional view of a power semiconductor device according to another exemplary embodiment of the present disclosure.

Referring to FIG. 2, a power semiconductor device 200 according to another exemplary embodiment of the present disclosure may include an n-type hole accumulation region 221 formed to be spaced apart from a trench gate 240 and formed below a hole movement region 222.

An impurity concentration of the hole accumulation region 221 may be higher than that of the drift region 210.

Therefore, the holes may be accumulated blow the hole accumulation region 221 and conductivity modulation may be significantly increased at the corresponding portion.

In the case in which the holes are accumulated, the hole current together with the conductivity modulation is increased, such that the possibility of latch-up generation is increased.

However, since the power semiconductor device 200 according to this exemplary embodiment of the present disclosure has the hole movement region 222, it may prevent the hole current from flowing into the emitter region 230, thereby preventing the latch-up.

That is, the power semiconductor device 200 according to this exemplary embodiment of the present disclosure may have a low turn-on voltage and high reliability.

In addition, since the power semiconductor device 200 according to this exemplary embodiment of the present disclosure has the hole accumulation region 221 spaced apart from the trench gate 240, it may prevent gate noise from being generated due to the accumulated holes.

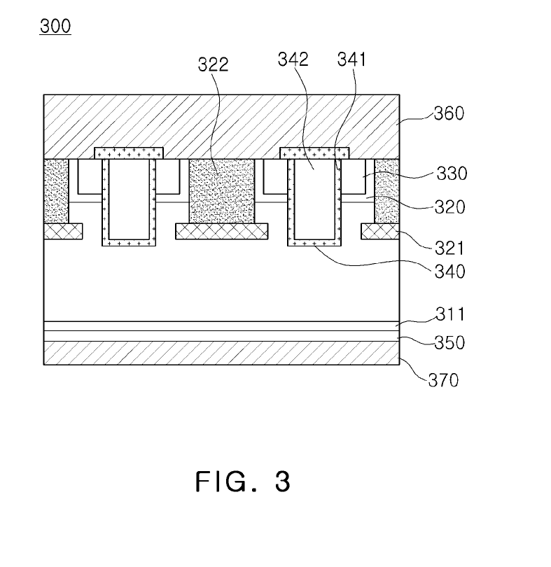

FIG. 3 illustrates a schematic cross-sectional view of a power semiconductor device 300 according to another exemplary embodiment of the present disclosure.

Referring to FIG. 3, a hole movement region 322 may be formed to contact a hole accumulation region 321.

Since the hole movement region 322 is formed to contact the hole accumulation region 321, holes accumulated in the hole accumulation region 321 may be more easily moved to the hole movement region 322.

Therefore, latch-up may be prevented in the power semiconductor device 300 according to this exemplary embodiment of the present disclosure, whereby reliability of the power semiconductor device 300 may be improved.

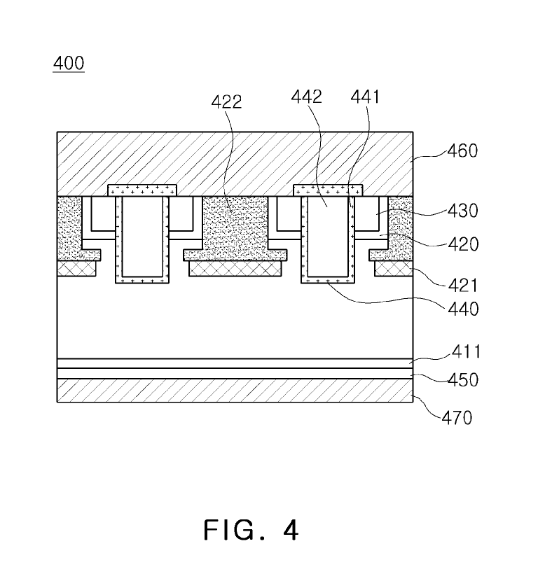

FIG. 4 illustrates a schematic cross-sectional view of a power semiconductor device 400 according to another exemplary embodiment of the present disclosure.

Referring to FIG. 4, a width of a hole movement region 422 may be greater than that of a hole accumulation region 421 in a portion in which the hole movement region 422 contacts the hole accumulation region 421.

Therefore, a hole current flowing in both sides of the hole accumulation region 421 may be easily introduced into the hole movement region 422.

Therefore, latch-up may be prevented in the power semiconductor device 400 according to this exemplary embodiment of the present disclosure, whereby reliability of the power semiconductor device 400 may be improved.

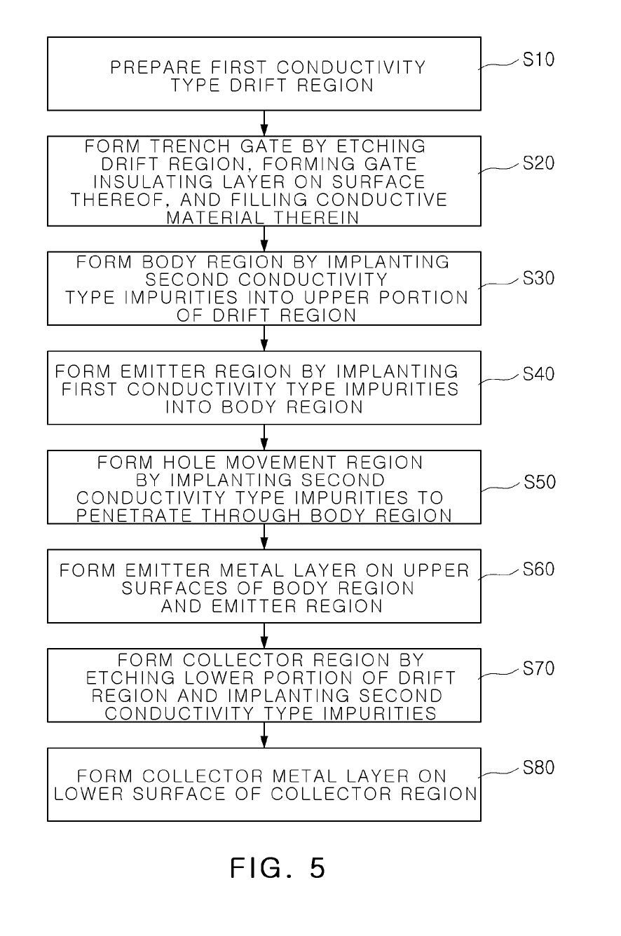

FIG. 5 is a flowchart schematically illustrating a method of manufacturing a power semiconductor device according to an exemplary embodiment of the present disclosure.

A method of manufacturing a power semiconductor device according to an exemplary embodiment of the present disclosure will be described with reference to FIG. 5.

First, a drift region having a first conductivity type may be prepared (S10).

The operation of preparing the drift region may be performed using an epitaxial method and may be performed to cause an impurity concentration to be low.

After the drift region is formed, a trench gate may be formed in an upper portion of the drift region (S20).

The operation of forming the trench gate may be performed to include an operation of etching the upper portion of the drift region, an operation of forming a gate insulating layer on a surface thereof, and filling a conductive material therein.

After the forming of the trench gate, a body region may be formed by implanting second conductivity type impurities into the upper portion of the drift region (S30).

Next, an emitter region may be formed by implanting first conductivity impurities into an upper portion of the body region (S40).

The operation of forming the emitter region may performed by forming a mask on the body region and by implanting the first conductivity impurities into a portion of the body region on which the mask is not formed.

After the emitter region is formed, a hole movement region may be formed (S50).

In order to form the hole movement region to be spaced apart from the trench gate, the mask may be formed on the body region.

In the operation of forming the hole movement region, the second conductivity type impurities are implanted at high concentration between the trench gates in a state in which they have high energy.

The concentration of the second conductivity type impurities implanted into the hole movement region may be higher than that of the body region.

Since the concentration of the second conductivity type impurities of the hole movement region is high, a hole current may be moved along the hole movement region, whereby latch-up may be prevented.

Next, an emitter metal layer may be formed on an upper surface of the power semiconductor device (S60).

After the emitter metal layer is formed, a collector region may be formed by removing a lower portion of the drift region to adjust a thickness of the drift region and implanting second conductivity type impurities into the lower portion of the drift region (S70).

Before the forming of the collector region, abutter region may be formed by implanting first conductivity type impurities at high concentration into the lower portion of the drift region.

After the forming of the collector region, a collector metal layer may be formed on a lower surface of the collector region (S80).

According to the method of manufacturing the power semiconductor device according to the exemplary embodiment of the present disclosure, a hole accumulation region may be formed before forming the hole movement region.

The hole accumulation region may be formed by implanting first conductivity type impurities having high energy level.

In the operation of forming the hole accumulation region, a depth of the hole accumulation region may be appropriately adjusted to be deeper than that of the hole movement region.

The hole accumulation region may have an impurity concentration higher than that of the drift region.

As set forth above, according to exemplary embodiments of the present invention, a power semiconductor device may decrease a hole current flowing in a lower portion of an emitter region by providing a hole movement region formed to penetrate through a body region, and accordingly, the occurrence of latch-up may be prevented, whereby reliability of the power semiconductor device may be improved.

In addition, a hole movement region decreases the resistance of the hole current, whereby performance of the power semiconductor device may be improved.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device, comprising:
a first semiconductor region of first conductivity type;
a second semiconductor region of second conductivity type disposed on the first semiconductor region;
a third semiconductor region of the first conductivity type disposed in an upper portion of the second semiconductor region;
a trench gate penetrating from the third semiconductor region to the first semiconductor region, having a gate insulating layer disposed on a surface thereof, and filled with a conductive material; and
a fourth semiconductor region of the second conductivity type penetrating through the second semiconductor region.

2. The power semiconductor device of claim 1, wherein the fourth semiconductor region has an impurity concentration higher than that of the second semiconductor region.

3. The power semiconductor device of claim 1, wherein the fourth semiconductor region is formed to be spaced apart from the trench gate.

4. The power semiconductor device of claim 1, further comprising a fifth semiconductor region having the first conductivity type and formed to be spaced apart from the trench gate below the fourth semiconductor region.

5. The power semiconductor device of claim 4, wherein the fifth semiconductor region is formed to contact the fourth semiconductor region.

6. The power semiconductor device of claim 4, wherein the fifth semiconductor region has an impurity concentration higher than that of the first semiconductor region.

7. A method of manufacturing a power semiconductor device, the method comprising:
preparing a first semiconductor region having a first conductivity type;
forming a trench gate by etching the first semiconductor region, forming a gate insulating layer on a surface thereof, and filling a conductive material therein;
forming a second semiconductor region by implanting second conductivity type impurities into an upper portion of the first semiconductor region;
forming a third semiconductor region by implanting first conductivity type impurities into an upper portion of the second semiconductor region; and
forming a fourth semiconductor region by implanting the second conductivity type impurities to be extended from the second semiconductor region to the first semiconductor region.

8. The method of claim 7, wherein the fourth semiconductor region is formed by implanting a greater amount of impurities than the second semiconductor region.

9. The method of claim 7, wherein in the forming of the fourth semiconductor region, the fourth semiconductor region is formed to be spaced apart from the trench gate.

10. The method of claim 7, further comprising forming a fifth semiconductor region to be spaced apart from the trench gate below the second semiconductor region by implanting the first conductivity type impurities.

11. The method of claim 10, wherein the fifth semiconductor region is formed to contact the fourth semiconductor region.

12. The method of claim 10, wherein the fifth semiconductor region is formed by implanting a greater amount of impurities than the first semiconductor region.
